(19) United States
(12) Patent Application Publication
(10) Pub. No.: US 2009/0206893 A1
(43) Pub. Date: Aug. 20, 2009

(54) CHARGE PUMP CIRCUIT AND PLL CIRCUIT

(75) Inventor: Ryota Terauchi, Yokohama-shi (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/388,753

(22) Filed: Feb. 19, 2009

(30) Foreign Application Priority Data
Feb. 20, 2008 (JP) 2008-38766

(51) Int. Cl. H03L 7/06; G05F 1/10

(52) U.S. Cl. 327/156; 327/536; 327/157

(57) ABSTRACT

PLL circuit 1000 includes a charge pump circuit 100, a low-pass filter 101, a voltage controlled oscillator 102, a frequency divider 103, and a phase comparator 104. As in the comparative example, the frequency divider 103 divides the frequency of an oscillation signal C and outputs a feedback signal B obtained by the frequency division. The phase comparator 104 compares the phase (frequency) of the feedback signal B and the phase (frequency) of an input signal A and outputs an output UP and an output DN according to the comparison result. The charge pump circuit 100 outputs a voltage corresponding to the output UP and the output DN. In other words, the charge pump circuit 100 outputs a signal by charging and discharging an input/output terminal in response to the output of the phase comparator 104.

### CROSS-REFERENCE TO RELATED APPLICATION

This application is based upon and claims the benefit of priority from the prior Japanese Patent Application No. 2008-38766, filed on Feb. 20, 2008, the entire contents of which are incorporated herein by reference.

### BACKGROUND OF THE INVENTION

1. Field of the Invention

The present invention relates to, for example, a charge pump circuit and a PLL circuit including the charge pump circuit.

2. Background Art

Phase locked loop (PLL) circuits generate clocks with desired frequencies and desired accuracy in integrated circuits. PLL circuits have been used for various products including a clock doubler, a clock recovery circuit, a clock circuit for a microprocessor, and a frequency synthesizer.

In a charge pump circuit used for a PLL circuit according to the prior art, a plurality of constant current sources are used and a plurality of switch elements turned on/off in response to the output signals of a phase comparator are used. The charge pump circuit is switched such that the constant current sources are always connected to the output of a single-stage operational amplifier and potentials are kept constant at the junctions of the constant current sources and the switch elements (for example, Japanese Patent Laid-Open No. 2000-286700).

This configuration reduces jitter on the output of the PLL circuit, the jitter being caused by charge sharing between the charge pump circuit and a low-pass filter.

In the charge pump circuit of the prior art, however, the operational amplifier is used and thus the power consumption has to be increased to achieve fast response.

### SUMMARY OF THE INVENTION

According to one aspect of the present invention, there is provided: a charge pump circuit, comprising:

an input/output terminal charged and discharged in response to input and output of a current;

a first constant current source having one end connected to a power supply;

a first switch element having one end connected to an other end of the first constant current source;

a second switch element having one end connected to an other end of the first switch element;

a second constant current source connected between an other end of the second switch element and ground;

a third constant current source having one end connected to the power supply;

a third switch element having one end connected to an other end of the third constant current source and an other end connected to a contact between the first switch element and the second switch element;

a fourth switch element having one end connected to the other end of the third switch element;

a fourth constant current source connected between an other end of the fourth switch element and the ground;

a fifth switch element having one end connected to the other end of the third constant current source and an other end connected to the input/output terminal; and

a sixth switch element connected between the input/output terminal and the fourth constant current source.

According to one aspect of the present invention, there is provided: a PLL circuit that outputs an oscillation signal, comprising:

a frequency divider that outputs a feedback signal obtained by dividing a frequency of the oscillation signal;

a phase comparator that compares a phase of the feedback signal and a phase of an input signal, and outputs a signal corresponding to a comparison result;

a charge pump circuit that has: an input/output terminal charged and discharged in response to input and output of a current; a first constant current source having one end connected to a power supply; a first switch element having one end connected to an other end of the first constant current source; a second switch element having one end connected to an other end of the first switch element; a second constant current source connected between an other end of the second switch element and ground; a third constant current source having one end connected to the power supply; a third switch element having one end connected to an other end of the third constant current source and an other end connected to a contact between the first switch element and the second switch element; a fourth switch element having one end connected to the other end of the third switch element; a fourth constant current source connected between an other end of the fourth switch element and the ground; a fifth switch element having one end connected to the other end of the third constant current source and an other end connected to the input/output terminal; and a sixth switch element connected between the input/output terminal and the fourth constant current source; and outputs a signal by charging and discharging the input/output terminal according to an output of the phase comparator;

a low-pass filter that filters an output of the charge pump circuit and outputs a control voltage obtained by filtering; and

a voltage controlled oscillator that outputs the oscillation signal and controls an oscillatory frequency of the oscillation signal according to the control voltage.

### BRIEF DESCRIPTION OF THE DRAWINGS

FIG. 1 is a block diagram showing a PLL circuit 1000a which is a charge pump circuit type serving as the comparative example;

FIG. 2 is a timing chart showing an example of the operation waveforms of the phase comparator 104 shown in FIG. 1;

FIG. 3A is a circuit diagram showing a state of the charge pump circuit 100a serving as the comparative example when the input signal A has a higher frequency than the feedback signal B in FIG. 2;

FIG. 3B is a circuit diagram showing a state of the charge pump circuit 100a serving as the comparative example when the feedback signal B has a higher frequency than the input signal A in FIG. 2;

FIG. 3C is a circuit diagram showing a state of the charge pump circuit 100a serving as the comparative example when the input signal A and the feedback signal B are equal in frequency in FIG. 2;

FIG. 4 is an explanatory drawing showing a state of an overshoot of the charge pump circuit 100a in the comparative example;

FIG. 5A is a graph showing the relationship between a time and a current passing through the constant current source on the ground side of the charge pump circuit in the comparative example;

FIG. 5B is a graph showing the relationship between a time and the voltage level of the output DN of the phase comparator;

FIG. 6 is a block diagram showing an example of the configuration of a PLL circuit 1000 according to a first embodiment which is an aspect of the present invention;

FIG. 7 is a circuit diagram showing the configuration of the charge pump circuit 100 according to the first embodiment shown in FIG. 6;

FIG. 8A is a circuit diagram showing a state of the charge pump circuit 100 when the input signal A has a higher frequency than the feedback signal B in FIG. 6;

FIG. 8B is a circuit diagram showing a state of the charge pump circuit 100 when the feedback signal B has a higher frequency than the input signal A in FIG. 6;

FIG. 8C is a circuit diagram showing a state of the charge pump circuit 100 when the input signal A and the feedback signal B are equal in frequency in FIG. 6;

FIG. 9A is a graph showing the relationship between a time and a current passing through the fourth constant current source of the charge pump circuit 100 according to the first embodiment;

FIG. 9B is a graph showing the relationship between a time and the voltage level of the output DN of the phase comparator 104;

FIG. 10 is a circuit diagram showing the configuration of the charge pump circuit 200 according to the second embodiment which is an aspect of the present invention; and

FIG. 11 is a circuit diagram showing the configuration of the charge pump circuit 300 according to the third embodiment which is an aspect of the present invention.

### DETAILED DESCRIPTION

### Comparative Example

As a comparative example, the following will examine a charge pump circuit capable of reducing power consumption without using an operational amplifier.

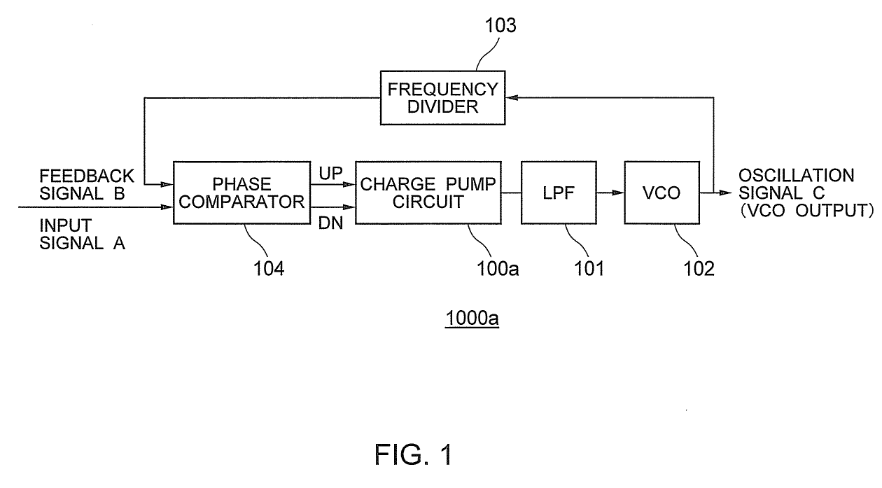

FIG. 1 shows a PLL circuit 1000a which is a charge pump circuit type serving as the comparative example.

As shown in FIG. 1, the PLL circuit 1000a includes a charge pump circuit 100a serving as the comparative example, a low-pass filter (LPF, loop filter) 101, a voltage controlled oscillator (VCO) 102, a frequency divider 103, and a phase comparator 104.

The frequency divider 103 divides the frequency of an oscillation signal C and outputs a feedback signal B.

The phase comparator 104 compares the phase (frequency) of the feedback signal B and the phase (frequency) of an input signal A and outputs an output UP and an output DN according to the comparison result.

The charge pump circuit 100a outputs a voltage corresponding to the output UP and the output DN.

The low-pass filter 101 filters (smoothes) the voltage outputted from the charge pump circuit 100a, and outputs a control voltage Vc obtained by the filtering.

The voltage controlled oscillator 102 outputs the oscillation signal C whose oscillatory frequency has been controlled according to the control voltage Vc.

In other words, when the input signal A has a higher frequency than the feedback signal B (the input signal A is phase advanced relative to the feedback signal B), the phase comparator 104 outputs the output UP and output DN according to the state. Next, the charge pump circuit 100a outputs a voltage according to the output UP and the output DN. After that, the low-pass filter 101 outputs the control voltage Vc so as to increase the frequency (phase advance) of the oscillation signal C outputted from the voltage controlled oscillator 102.

Similarly, when the input signal A has a lower frequency than the feedback signal B (the input signal A is phase delayed relative to the feedback signal B), the phase comparator 104 outputs the output UP and the output DN according to the state. Next, the charge pump circuit 100a outputs a voltage according to the output UP and the output DN. After that, the low-pass filter 101 outputs the control voltage Vc so as to reduce the frequency (phase delay) of the oscillation signal C outputted from the voltage controlled oscillator 102.

Through the operations of the PLL circuit 1000a, the feedback signal B and the input signal A are synchronized with each other and the oscillation signal C is controlled to have a desired oscillatory frequency.

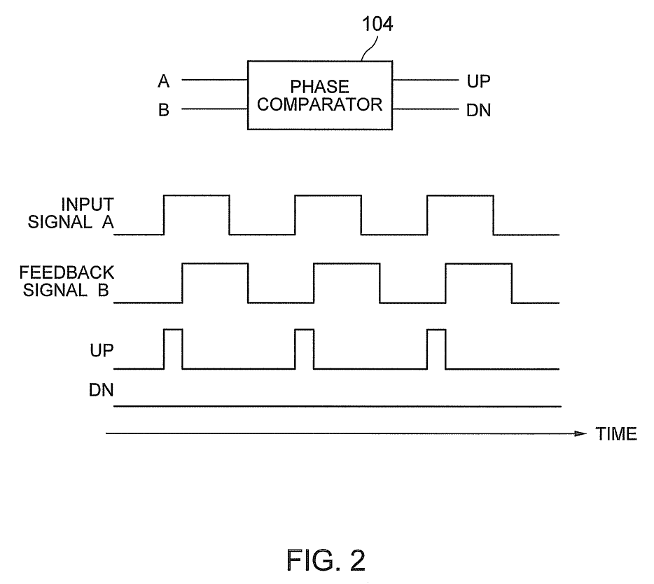

FIG. 2 shows an example of the operation waveforms of the phase comparator 104 shown in FIG. 1.

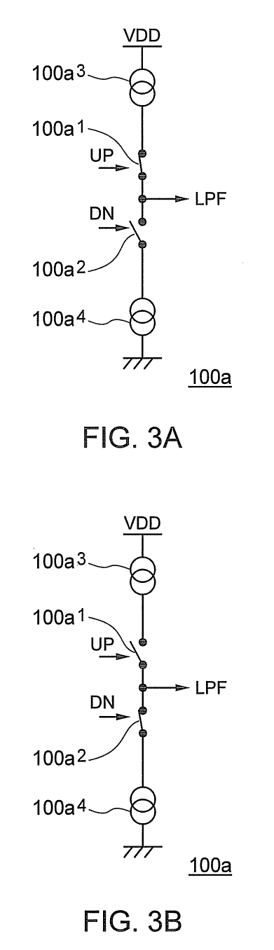

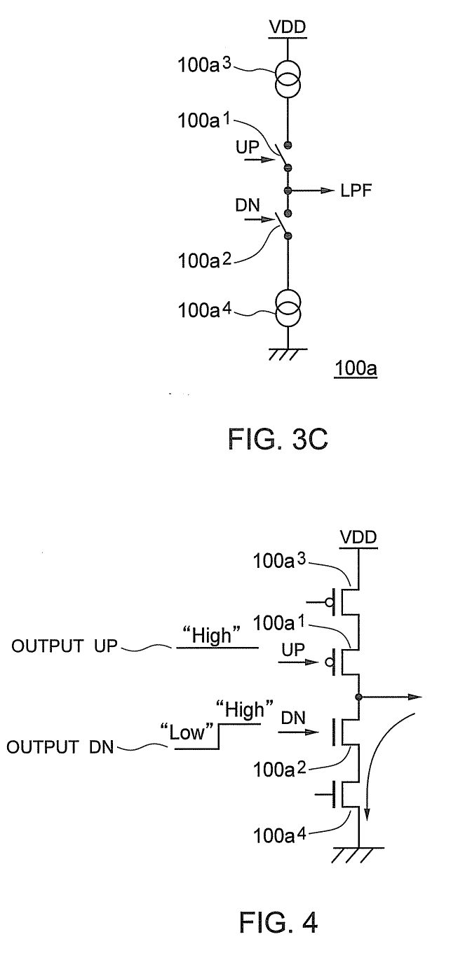

FIG. 3A shows a state of the charge pump circuit 100a serving as the comparative example when the input signal A has a higher frequency than the feedback signal B in FIG. 2. FIG. 3B shows a state of the charge pump circuit 100a serving as the comparative example when the feedback signal B has a higher frequency than the input signal A in FIG. 2. FIG. 3C shows a state of the charge pump circuit 100a serving as the comparative example when the input signal A and the feedback signal B are equal in frequency in FIG. 2.

When the input signal A of the phase comparator 104 has a higher frequency than the feedback signal B, that is, in the case of ωA>ωB, the output UP of the phase comparator 104 is “1” (a logic for turning on switch elements) and the output DN is “0” (a logic for turning off the switch elements).

At this point, as shown in FIG. 3A, a switch element 100a1 is turned on and a switch element 100a2 is turned off in the charge pump circuit 100a.

When the feedback signal B of the phase comparator 104 has a higher frequency than the input signal A, that is, in the case of ωA<ωB, the output UP is “0” and the output DN is “1”.

At this point, as shown in FIG. 3B, the switch element 100a1 is turned off and the switch element 100a2 is turned on in the charge pump circuit 100a.

When the feedback signal B of the phase comparator 104 is equal in frequency to the input signal A, that is, in the case of ωA=ωB, the output UP is “0” and the output DN is “0”.

At this point, as shown in FIG. 3C, the switch element 100a1 is turned off and the switch element 100a2 is turned off in the charge pump circuit 100a.

In this case, a difference between the output UP and the output DN is a phase difference or a frequency difference between the input signal A and the feedback signal B, and an output pulse corresponding to the difference is inputted to the charge pump circuit 100a. Further, the input/output current of the charge pump circuit 100a is filtered by the low-pass filter 101 and is supplied to the voltage controlled oscillator 102.

When the feedback signal B is phase delayed relative to the input signal A, the positive pulse (“1”) of the output UP is inputted to the charge pump circuit 100a. Thus the charge pump circuit 100a enters the state of FIG. 3A and outputs a current, and then the charge pump circuit 100a controls the input signal (control voltage Vc) of the voltage controlled oscillator 102 so as to increase the frequency of the feedback signal B.

When the feedback signal B is phase advanced relative to the input signal A, the positive pulse (“1”) of the output DN is inputted to the charge pump circuit 100a. Thus the charge pump circuit 100a enters the state of FIG. 3B and draws a current, and then the charge pump circuit 100a controls the input signal (control voltage Vc) of the voltage controlled oscillator 102 so as to reduce the frequency of the feedback signal B.

When the feedback signal B is equal in phase to the input signal, the output UP is “0” and the output DN is “0”. Thus the charge pump circuit 100a enters the state of FIG. 3C and controls the input signal (control voltage Vc) of the voltage controlled oscillator 102 so as to keep the frequency of the feedback signal B.

In the above example, the output frequency of the voltage controlled oscillator increases with the control voltage Vc. The output frequency of the voltage controlled oscillator may increase as the control voltage Vc decreases.

The following will describe the problems of the charge pump circuit 100a of the comparative example.

The charge pump circuit 100a of the comparative example may have an overshoot on the input/output current at the moment when the switch elements are turned on. FIG. 4 is an explanatory drawing showing a state of an overshoot of the charge pump circuit 100a in the comparative example. In FIG. 4, the switch element 100a1 acts as a pMOS transistor and the switch element 100a2 acts as an nMOS transistor. A constant current source 100a3 is a PMOS transistor having the gate fed with a fixed voltage, and a constant current source 100a4 is an nMOS transistor having the gate fed with the fixed voltage.

In FIG. 4, first, when the output DN is “0”, that is, at “Low” level in a state in which the output UP is “0”, that is, at “High” level, the switch element 100a1 is turned off and the switch element 100a2 is turned off. In this case, since the switch element 100a2 is turned off, the constant current source (nMOS transistor) 100a4 cannot pass a current. For this reason, the drain voltage of the nMOS transistor 100a4 decreases close to grounding.

Next, when the output DN is switched to “1”, that is, “High” level in a state in which the output UP is “0”, that is, at “High” level, the switch element 100a2 is turned on. The output resistance of the constant current source 100a4 is set low, and thus the constant current source 100a4 is fed with a current having a predetermined value or higher. After that, the constant current source (nMOS transistor) 100a4 is saturated and a drain voltage is stabilized at a desired voltage.

The same holds true for the constant current source 100a3 on the side of the output UP.

As described above, because of a change of an input/output resistance generated at the switching of the switch elements 100a1 and 100a2, the input/output current of the charge pump circuit 100a has an overshoot at the moment when the switch elements 100a1 and 100a2 are turned on.

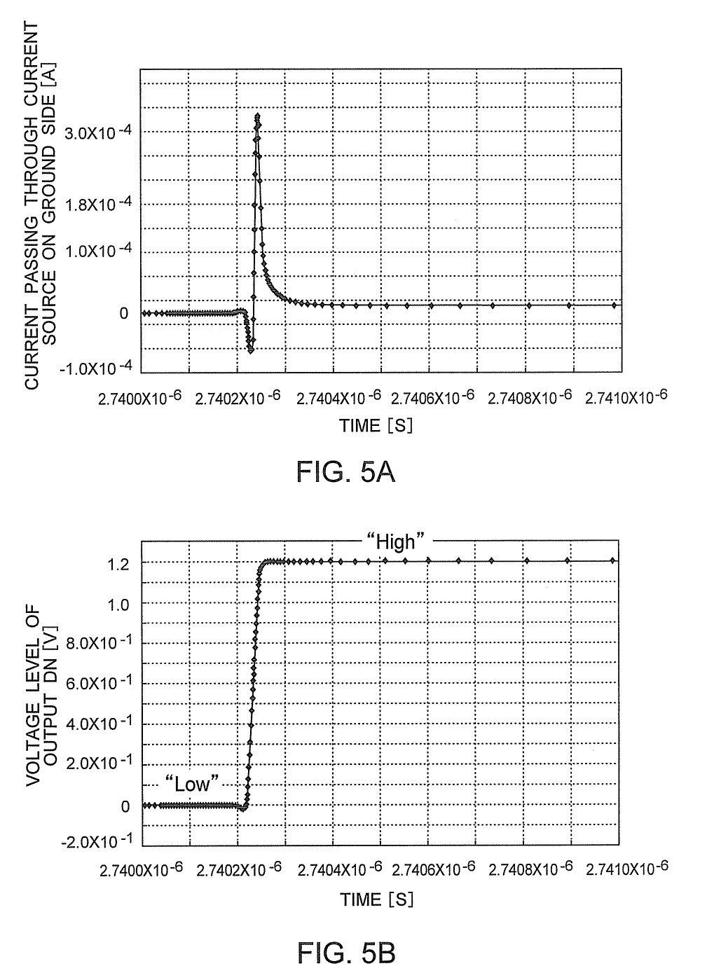

FIG. 5A shows the relationship between a time and a current passing through the constant current source on the ground side of the charge pump circuit in the comparative example. FIG. 5B shows the relationship between a time and the voltage level of the output DN of the phase comparator.

FIGS. 5A and 5B show that immediately after the voltage level of the output DN of the phase comparator 104 is switched from “Low” level to “High” level, a current passing through the constant current source 100a4 increases (overshoots) to 300 uA or higher. Such an overshoot changes the input signal (control voltage Vc) of the voltage controlled oscillator 102. Thus the oscillatory frequency of the voltage controlled oscillator 102 may change and cause frequency jitter on a PLL output.

Further, an amount of overshoot considerably depends upon a difference in the amount of current between the nMOS transistor and the pMOS transistor and is also susceptible to process fluctuations.

Thus variations in the amount of overshoot may cause a phase error on the input signal A and the feedback signal B.

Thus in embodiments to which the present invention is applied, charge pump circuits are proposed which can reduce an overshoot current generated at the switching of input/output currents while reducing power consumption. Thus jitter can be reduced on the output (oscillation signal) of a PLL circuit.

The embodiments to which the present invention is applied will be described below in accordance with the accompanying drawings.

### FIRST EMBODIMENT

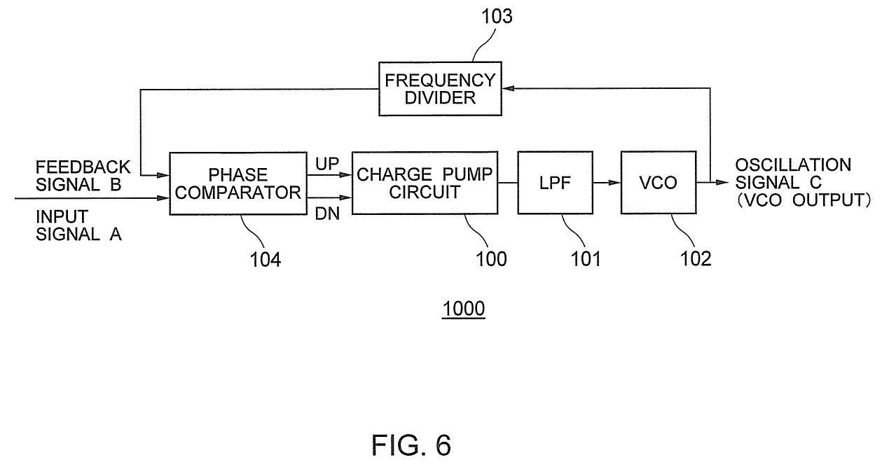

FIG. 6 shows an example of the configuration of a PLL circuit 1000 according to a first embodiment which is an aspect of the present invention. In FIG. 6, the same reference numerals as in FIG. 1 indicate the same configurations as FIG. 1. As shown in FIG. 6, the PLL circuit 1000 includes a charge pump circuit 100, a low-pass filter 101, a voltage controlled oscillator 102, a frequency divider 103, and a phase comparator 104.

As in the comparative example, the frequency divider 103 divides the frequency of an oscillation signal C and outputs a feedback signal B obtained by the frequency division.

The phase comparator 104 compares the phase (frequency) of the feedback signal B and the phase (frequency) of an input signal A and outputs an output UP and an output DN according to the comparison result.

The charge pump circuit 100 outputs a voltage corresponding to the output UP and the output DN. In other words, the charge pump circuit 100 outputs a signal by charging and discharging an input/output terminal in response to the output of the phase comparator 104.

The low-pass filter 101 filters (smoothes) the voltage outputted from the charge pump circuit 100, and outputs a control voltage Vc obtained by the filtering.

The voltage controlled oscillator 102 outputs the oscillation signal C whose oscillatory frequency has been controlled according to the control voltage Vc.

In other words, when the input signal A has a higher frequency than the feedback signal B (the input signal A is phase advanced relative to the feedback signal B), the phase comparator 104 outputs the output UP and output DN according to the state. Next, the charge pump circuit 100 outputs a voltage according to the output UP and the output DN. After that, the low-pass filter 101 outputs the control voltage Vc so as to increase the frequency (phase advance) of the oscillation signal C outputted from the voltage controlled oscillator 102.

Similarly, when the input signal A has a lower frequency than the feedback signal B (the input signal A is phase delayed relative to the feedback signal B), the phase comparator 104 outputs the output UP and the output DN according to the state. Next, the charge pump circuit 100 outputs a voltage according to the output UP and the output DN. After that, the low-pass filter 101 outputs the control voltage Vc so as to reduce the frequency (phase delay) of the oscillation signal C outputted from the voltage controlled oscillator 102.

Through the operations of the PLL circuit 1000, the feedback signal B and the input signal A are synchronized with each other and the oscillation signal C is controlled to have a desired oscillatory frequency.

A difference between the output UP and the output DN is, for example, a phase difference or a frequency difference between the input signal A and the feedback signal B, and an output pulse corresponding to the difference is inputted to the charge pump circuit 100. Further, the input/output current of the charge pump circuit 100 is filtered by the low-pass filter 101 and is supplied to the voltage controlled oscillator 102 as the control voltage Vc.

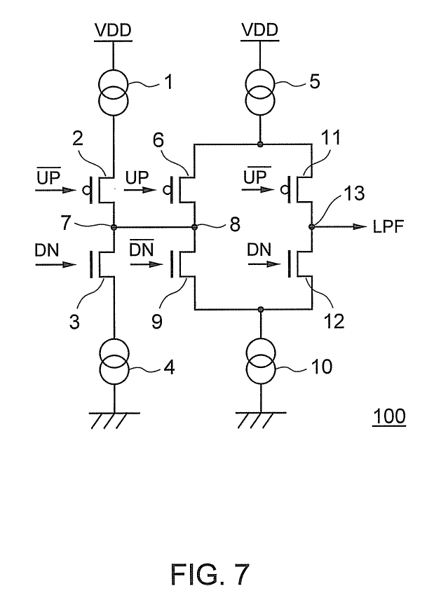

FIG. 7 is a circuit diagram showing the configuration of the charge pump circuit 100 according to the first embodiment shown in FIG. 6.

As shown in FIG. 7, the charge pump circuit 100 includes a first constant current source 1, a first switch element 2, a second switch element 3, a second constant current source 4, a third constant current source 5, a third switch element 6, a fourth switch element 9, a fourth constant current source 10, a fifth switch element 11, a sixth switch element 12, and an input/output terminal 13.

The first constant current source 1 has one end connected to a power supply VDD. The first constant current source 1 is made up of, for example, a MOS transistor having the gate fed with a constant voltage.

The first switch element 2 is made up of, for example, a pMOS transistor. The first switch element 2 has one end (source) connected to the other end of the first constant current source 1 and the gate fed with an output/UP obtained by reversing the phase of the output UP of the phase comparator 104.

The second switch element 3 is made up of, for example, an nMOS transistor. The second switch element 3 has one end (drain) connected to the other end (drain) of the first switch element 2 and the gate fed with the output DN of the phase comparator 104.

The second constant current source 4 is connected between the other end (source) of the second switch element 3 and the ground. The second constant current source 4 is made up of, for example, a MOS transistor having the gate fed with the constant voltage.

The third constant current source 5 has one end connected to the power supply VDD. The first constant current source 1 is made up of, for example, a MOS transistor having the gate fed with the constant voltage.

The third switch element 6 is made up of, for example, a pMOS transistor. The third switch element 6 has one end (source) connected to the other end of the third constant current source 5, the other end (drain) connected to a contact 7 (via a contact 8) between the first switch element 2 and the second switch element 3, and the gate fed with the output UP.

The fourth switch element 9 is made up of, for example, an nMOS transistor. The fourth switch element 9 has one end (drain) connected to the other end (drain) of the third switch element 6 (to the contact 8) and has the gate fed with an output/DN obtained by reversing the phase of the output DN.

The fourth constant current source 10 is connected between the other end (source) of the fourth switch element 9 and the ground. The fourth constant current source 10 is made up of, for example, a MOS transistor having the gate fed with the constant voltage.

The fifth switch element 11 is made up of, for example, a PMOS transistor. The fourth switch element 10 has one end (source) connected to the other end of the third constant current source 5, the other end (drain) connected to the input/output terminal 13, and the gate fed with the output/UP.

The sixth switch element 12 is made up of, for example, an nMOS transistor. The sixth switch element 12 is connected between the input/output terminal 13 (the other end (drain) of the fifth switch element 11) and the fourth constant current source 10 and has the gate fed with the output DN.

The input/output terminal 13 is a terminal for inputting and outputting a charge pump circuit current. The input/output terminal 13 is connected to the input of the low-pass filter 101.

The input/output terminal 13 is charged by a current supplied from the third constant current source 5. Further, the input/output terminal 13 is charged by supplying a current to the fourth constant current source 10, so that a signal is outputted to the low-pass filter 101.

The first to fourth constant current sources 1, 4, 5, and 10 are all set to output equal constant currents.

The first, third, and fifth switch elements 2, 6, and 11, which are pMOS transistors, are set to have equal transistor sizes.

The second, fourth, and sixth switch elements 3, 9, and 12, which are nMOS transistors, are set to have equal transistor sizes.

The following will describe the operations of the charge pump circuit 100 configured thus.

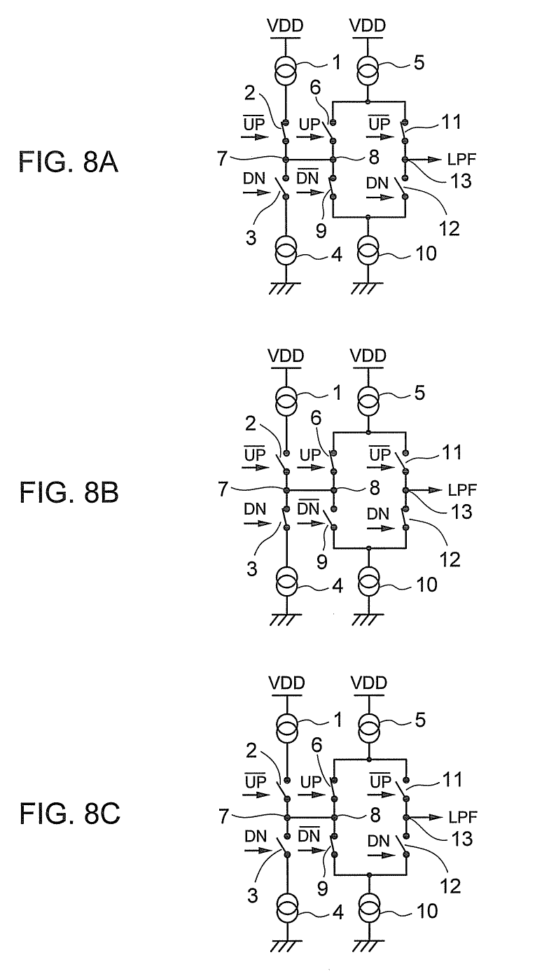

FIG. 8A shows a state of the charge pump circuit 100 when the input signal A has a higher frequency than the feedback signal B in FIG. 6. FIG. 8B shows a state of the charge pump circuit 100 when the feedback signal B has a higher frequency than the input signal A in FIG. 6. FIG. 8C shows a state of the charge pump circuit 100 when the input signal A and the feedback signal B are equal in frequency in FIG. 6.

In FIGS. 8A to 8C, MOS transistors are illustrated as switch elements for explanation.

When the input signal A has a higher frequency than the feedback signal B, that is, in the case of ωA>ωB, the phase comparator 104 sets, for example, the output UP at “0” (a logic for turning off the switch elements) and the output DN at “0”. At this point, the charge pump circuit 100 charges, for example, the input/output terminal 13.

In other words, as shown in FIG. 8A, when charging the input/output terminal 13, the charge pump circuit 100 turns on the first switch element 2, the fourth switch element 9, and the fifth switch element 11 and turns off the second switch element 3, the third switch element 6, and the sixth switch element 12.

Thus the output current of the third constant current source 5 is outputted to the input/output terminal 13. Further, the output current of the first constant current source 1 flows to the fourth constant current source 10 through the first switch element 2 and the fourth switch element 9.

In other words, the charge pump circuit 100 outputs a current and controls the input signal (control voltage Vc) of the voltage controlled oscillator 102 so as to increase the frequency of the feedback signal B.

When the feedback signal B has a higher frequency than the input signal A, that is, in the case of ωA<ωB, the phase comparator 104 sets, for example, the output UP at “1” (a logic for turning on the switch elements) and the output DN at “1”. At this point, the charge pump circuit 100 discharges, for example, the input/output terminal 13.

In other words, as shown in FIG. 8B, when the input/output terminal 13 is discharged, the charge pump circuit 100 turns off the first switch element 2, the fourth switch element 9, and the fifth switch element 11 and turns on the second switch element 3, the third switch element 6, and the sixth switch element 12.

Thus a current is outputted from the input/output terminal 13 to the fourth constant current source 10. Further, the output current of the third constant current source 5 flows to the second constant current source 4 through the third switch element 6 and the second switch element 3.

In other words, the charge pump circuit 100 draws a current and controls the input signal (control voltage Vc) of the voltage controlled oscillator 102 so as to reduce the frequency of the feedback signal B.

When the feedback signal B is equal in frequency to the input signal A, that is, in the case of ωA=ωB, the phase comparator 104 sets, for example, the output UP at “1” and the output DN at “ ”.

At this point, the charge pump circuit 100 does not charge or discharge, for example, the input/output terminal 13. In other words, as shown in FIG. 8C, when the input/output terminal 13 is not charged or discharged, the charge pump circuit 100 turns off the first switch element 2, the second switch element 3, the fifth switch element 11, and the sixth switch element 12 and turns on the third switch element 6 and the fourth switch element 9.

Thus the input/output terminal 13 is not charged or discharged. Further, the output current of the third constant current source 5 flows to the fourth constant current source 10 through the third switch element 6 and the fourth switch element 9.

In other words, the charge pump circuit 100 controls the input signal (control voltage Vc) of the voltage controlled oscillator 102 so as to keep the frequency of the feedback signal B.

As described above, when the charge pump circuit 100 performs the charging/discharging operation and the keeping operation shown in FIGS. 8A to 8C, the third and fourth constant current sources 5 and 10 connected to the input/output terminal 13 via the switch elements are operated all the time and continue passing constant currents.

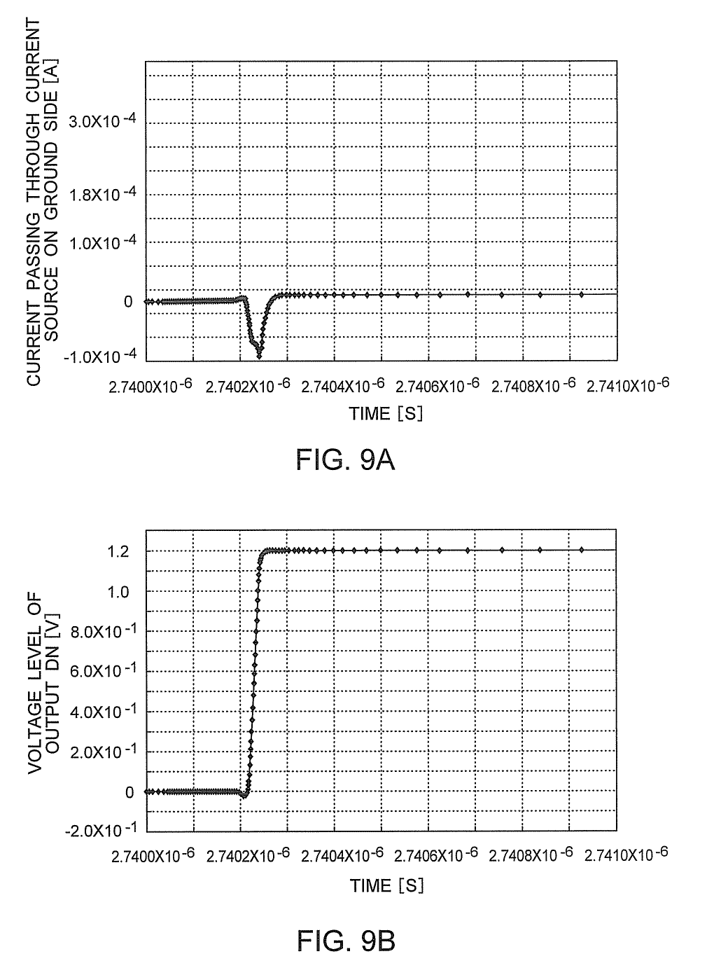

FIG. 9A shows the relationship between a time and a current passing through the fourth constant current source of the charge pump circuit 100 according to the first embodiment. FIG. 9B shows the relationship between a time and the voltage level of the output DN of the phase comparator 104.

FIGS. 9A and 9B show that immediately after the voltage level of the output DN of the phase comparator 104 is switched from “Low” level to “High” level, the overshoot of a current passing through a current source 100a4 is more suppressed than in the comparative example (FIGS. 5A and 5B).

As described above, even though the state of the charge pump circuit 100 is switched, the third and fourth constant current sources continue passing constant currents.

Thus fluctuations in the resistance of the charge pump circuit 100 are small when viewed from the input/output terminal 13. Thus it is possible to reduce a overshoot occurring at the switching of the current of the charge pump circuit 100.

As described above, the charge pump circuit of the present embodiment can suppress the overshoot of the output while reducing current consumption. Thus it is possible to reduce jitter on the output (oscillation signal) of the PLL circuit.

As described above, in the present embodiment, an increase in the control voltage Vc corresponds to an increase in the output frequency of the voltage controlled oscillator. The output frequency of the voltage controlled oscillator may be increased by reducing the control voltage Vc.

### SECOND EMBODIMENT

The first embodiment described an example of the configuration of the charge pump circuit which suppresses the overshoot of an output while reducing current consumption.

A second embodiment will particularly describe an example of a configuration for further reducing fluctuations in current passing through third and fourth constant current sources.

A charge pump circuit 200 of the second embodiment is also applicable to a PLL circuit 1000 like the charge pump circuit 100 of the first embodiment.

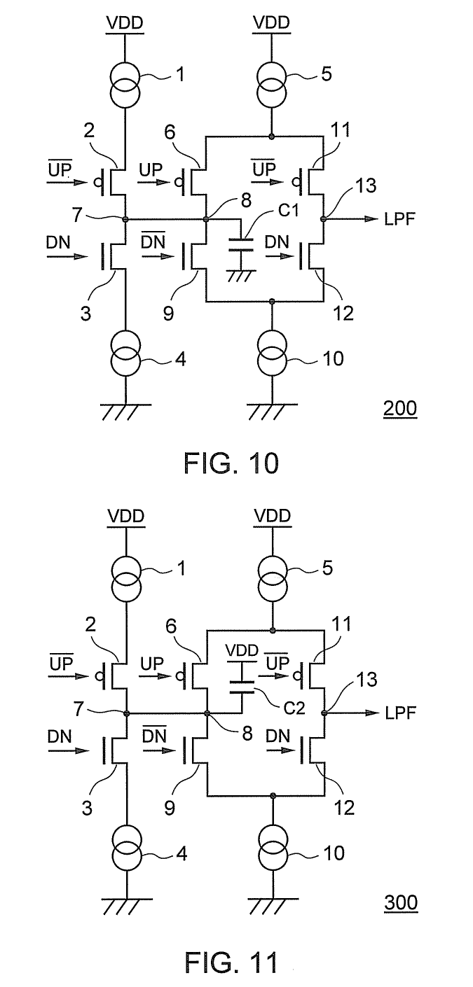

FIG. 10 is a circuit diagram showing the configuration of the charge pump circuit 200 according to the second embodiment which is an aspect of the present invention. In FIG. 10, the same reference numerals as in FIG. 7 indicate the same configurations as the first embodiment.

As shown in FIG. 10, the charge pump circuit 200 further includes a capacitor C1 connected between a contact 8 and the ground, unlike the charge pump circuit 100 of the first embodiment. Other configurations are the same as the configurations of the first embodiment.

Although the charge pump circuit 200 operates as in the first embodiment, the addition of the capacitor C1 can suppress fluctuations in potential generated on the contact 8 at the switching of the state of the charge pump circuit 200.

Thus it is possible to further suppress fluctuations in current in third and fourth constant current sources 5 and 10 as compared with the first embodiment. In other words, it is possible to further suppress an overshoot generated at the switching of the current of the charge pump circuit 200.

As described above, the charge pump circuit of the present embodiment can suppress the overshoot of the output while reducing current consumption. Thus it is possible to reduce jitter on the output (oscillation signal) of a PLL circuit.

### THIRD EMBODIMENT

The second embodiment described an example of the configuration for further reducing fluctuations in current passing through the third and fourth constant current sources.

A third embodiment will particularly describe another example of the configuration for reducing fluctuations in current passing through third and fourth constant current sources.

A charge pump circuit 300 of the third embodiment is also applicable to a PLL circuit 1000 like the charge pump circuit 100 of the first embodiment.

FIG. 11 is a circuit diagram showing the configuration of the charge pump circuit 300 according to the third embodiment which is an aspect of the present invention. In FIG. 11, the same reference numerals as in FIG. 7 indicate the same configurations as the first embodiment.

As shown in FIG. 11, the charge pump circuit 300 further includes a capacitor C2 connected between a contact 8 and a power supply VDD, unlike the charge pump circuit 100 of the first embodiment. Other configurations are the same as the configurations of the first embodiment.

Although the charge pump circuit 300 operates as in the first embodiment, the addition of the capacitor C2 can suppress fluctuations in potential generated on the contact 8 at the switching of the state of the charge pump circuit 300.

Thus it is possible to further suppress fluctuations in current in third and fourth constant current sources 5 and 10 as compared with the first embodiment. In other words, it is possible to further suppress an overshoot generated at the switching of the current of the charge pump circuit 300.

As described above, the charge pump circuit of the present embodiment can suppress the overshoot of the output while reducing current consumption. Thus it is possible to reduce jitter on the output (oscillation signal) of a PLL circuit.

What is claimed is:

1. A charge pump circuit, comprising:
an input/output terminal charged and discharged in response to input and output of a current;
a first constant current source having one end connected to a power supply;
a first switch element having one end connected to an other end of the first constant current source;
a second switch element having one end connected to an other end of the first switch element;
a second constant current source connected between an other end of the second switch element and ground;
a third constant current source having one end connected to the power supply;
a third switch element having one end connected to an other end of the third constant current source and an other end connected to a contact between the first switch element and the second switch element;
a fourth switch element having one end connected to the other end of the third switch element;
a fourth constant current source connected between an other end of the fourth switch element and the ground;
a fifth switch element having one end connected to the other end of the third constant current source and an other end connected to the input/output terminal; and
a sixth switch element connected between the input/output terminal and the fourth constant current source.

2. The charge pump circuit according to claim 1, wherein when the input/output terminal is charged,
the first switch element, the fourth switch element, and the fifth switch element are turned on and the second switch element, the third switch element, and the sixth switch element are turned off;
when the input/output terminal is discharged,
the first switch element, the fourth switch element, and the fifth switch element are turned off and the second switch element, the third switch element, and the sixth switch element are turned on; and
when the input/output terminal is not charged or discharged,
the first switch element, the second switch element, the fifth switch element, and the sixth switch element are turned off and the third switch element and the fourth switch element are turned on.

3. The charge pump circuit according to claim 1, further comprising a capacitor connected between the contact and the power supply.

4. The charge pump circuit according to claim 1, further comprising a capacitor connected between the contact and the ground.

5. The charge pump circuit according to claim 1, wherein the first to fourth constant current sources are set to output equal constant currents.

6. A PLL circuit that outputs an oscillation signal, comprising:
a frequency divider that outputs a feedback signal obtained by dividing a frequency of the oscillation signal;
a phase comparator that compares a phase of the feedback signal and a phase of an input signal, and outputs a signal corresponding to a comparison result;
a charge pump circuit that has: an input/output terminal charged and discharged in response to input and output of a current; a first constant current source having one end connected to a power supply; a first switch element having one end connected to an other end of the first constant current source; a second switch element having one end connected to an other end of the first switch element; a second constant current source connected between an other end of the second switch element and ground; a third constant current source having one end connected to the power supply; a third switch element having one end connected to an other end of the third constant current source and an other end connected to a contact between the first switch element and the second switch element; a fourth switch element having one end connected to the other end of the third switch element; a fourth constant current source connected between an other end of the fourth switch element and the ground; a fifth switch element having one end connected to the other end of the third constant current source and an other end connected to the input/output terminal; and a sixth switch element connected between the input/output terminal and the fourth constant current source; and outputs a signal by charging and discharging the input/output terminal according to an output of the phase comparator;
a low-pass filter that filters an output of the charge pump circuit and outputs a control voltage obtained by filtering; and
a voltage controlled oscillator that outputs the oscillation signal and controls an oscillatory frequency of the oscillation signal according to the control voltage.

7. The PLL circuit according to claim 6, wherein when the input/output terminal is charged,
the first switch element, the fourth switch element, and the fifth switch element are turned on and the second switch element, the third switch element, and the sixth switch element are turned off;
when the input/output terminal is discharged,
the first switch element, the fourth switch element, and the fifth switch element are turned off and the second switch element, the third switch element, and the sixth switch element are turned on; and
when the input/output terminal is not charged or discharged,
the first switch element, the second switch element, the fifth switch element, and the sixth switch element are turned off and the third switch element and the fourth switch element are turned on.

8. The PLL circuit according to claim 6, further comprising a capacitor connected between the contact and the power supply.

9. The PLL circuit according to claim 6, further comprising a capacitor connected between the contact and the ground.

10. The PLL circuit according to claim 6, wherein the first to fourth constant current sources are set to output equal constant currents.
